(19) United States
(12) Patent Application Publication
(10) Pub. No.: US 2010/0207878 A1
(43) Pub. Date: Aug. 19, 2010

(54) ILLUMINATION DEVICE, METHOD FOR FABRICATING THE SAME, AND SYSTEM FOR DISPLAYING IMAGES UTILIZING THE SAME

(75) Inventors: Ryuji Nishikawa, Hsinchu City (TW); Hsiang-Lun Hsu, Miaoli City (TW); Po-Kun Su, Sijhih City (TW); Du-Zen Peng, Jhubei City (TW)

Correspondence Address: LIU & LIU, 444 S. FLOWER STREET, SUITE 1750, LOS ANGELES, CA, 90071, US

(73) Assignee: TPO Displays Corp., Chu-Nan (TW)

(21) Appl. No.: 12/704,491

(22) Filed: Feb. 11, 2010

(30) Foreign Application Priority Data
Feb. 13, 2009 (TW) 098104611

(51) Int. Cl. H01L 27/32; G06F 3/01; H01L 51/56

(52) U.S. Cl. 345/156; 313/1; 445/33

(57) ABSTRACT

The invention provides an illumination device, method for fabricating the same, and system for displaying images utilizing the same. The illumination device includes a substrate, a first electrode, an illumination layer, and a second electrode. The substrate has a plurality of illumination regions. The first electrode overlies the substrate and has a first bump disposed in a first illumination region of the plurality of the illumination regions. The illumination layer overlies the first electrode. The second electrode overlies the illumination layer.

### CROSS REFERENCE TO RELATED APPLICATIONS

This Application claims priority of Taiwan Patent Application No. 098104611, filed on Feb. 13, 2009, the entirety of which is incorporated by reference herein.

### BACKGROUND OF THE INVENTION

1. Field of the Invention

The invention relates to illumination devices of systems for displaying images.

2. Description of the Related Art

Colorimetric purity provided by an organic light emitting diode (OLED) is important for full color flat panel displays employing OLEDs. The OLED may utilize microcavity effect, wherein emitted light of specific wavelengths are enhanced by the constructive interference thereof, and emitted light of other specific wavelengths are weakened by the destructive interference thereof, such that the full width at half maximum (FWHM) of the emitted light is narrowed. Specifically, a transflective electrode is formed in a light-emitting part of an illumination device and a reflective electrode is formed in an opposite side to the transflective electrode to induce interference of photons from an illumination layer of the illumination device between the transflective and reflective electrodes. The intensity of light with specific colors in emitted light from the OLED can be enhanced by controlling the microcavities. Thus, light with better colorimetric purity can be obtained by obtainment of trichromatic light utilizing a light filtration material, resulting in lower light loss due to light filtration, decreasing energy (electrical power) consumption.

U.S. Pat. No. 7,129,634 and SID 04 DIGEST (pages 1017-1019) disclose OLEDs utilized in display devices where transparent microcavity spacer layers and transparent electrodes with different thicknesses are respectively disposed in pixel areas of different colors. However, because the transparent microcavity spacer layer and transparent electrode in one single pixel area respectively have constant thicknesses, multiple deposition and etching steps are required for different thicknesses, complicating the fabrication process and increasing costs.

Thus, a novel illumination device, method for fabricating the same, and system for displaying images utilizing the same are required to solve the described problems.

### BRIEF SUMMARY OF THE INVENTION

An embodiment of the present invention provides an illumination device. The illumination device includes a substrate, a first electrode, an illumination layer, and a second electrode. The substrate comprises a plurality of illumination regions. The first electrode overlies the substrate and comprises a first bump disposed in a first illumination region of the plurality of the illumination regions. The illumination layer overlies the first electrode. The second electrode is deposited on the illumination layer.

An embodiment of the present invention provides a system for displaying images, which includes a display panel and an input unit. The display panel comprises the forward illumination device. The input unit is coupled to the display panel and provides an input signal to the display panel for displaying images.

An embodiment of the present invention provides a method for fabricating an illumination device. First, a substrate comprising a plurality of illumination regions having a first illumination region and a second illumination region is provided. Then, an electrode base layer of a first electrode is formed on the substrate in each of the plurality of illumination regions. Next, a first island-like transparent layer of the first electrode is formed in the first illumination region on the substrate. Further, an illumination layer is deposited on the first electrode. Finally, a second electrode is formed on the illumination layer.

Further scope of the applicability of the invention will become apparent from the detailed descriptions given hereinafter. It should be understood however, that the detailed descriptions and specific examples, while indicating preferred embodiments of the invention, are given by way of illustration only, as various changes and modifications within the spirit and scope of the invention will become apparent to those skilled in the Art from the detailed descriptions.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows an exemplary top view of an illumination device of a preferred embodiment of the invention;

FIGS. 2A through 2C show exemplary top views of the arrangements of bumps of a preferred embodiment of the invention;

FIG. 3A schematically shows a system for displaying images of a preferred embodiment of the invention; and

FIG. 3B shows a schematic layout of a display panel of a preferred embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Next, the concepts and specific practice modes of the invention is described in detail by the embodiments and the attached drawings. In the drawings or description, similar elements are indicated by similar reference numerals and/or letters. Further, the element shape or thickness in the drawings can be expanded for simplification or convenience of indication. Moreover, elements which are not shown or described can be in every form known by those skilled in the art.

Specific embodiments of the present invention for fabrication of an illumination device and a system for displaying images are described. It is noted that the concepts of the invention can be applied to any known or newly developed illumination devices and systems for displaying images.

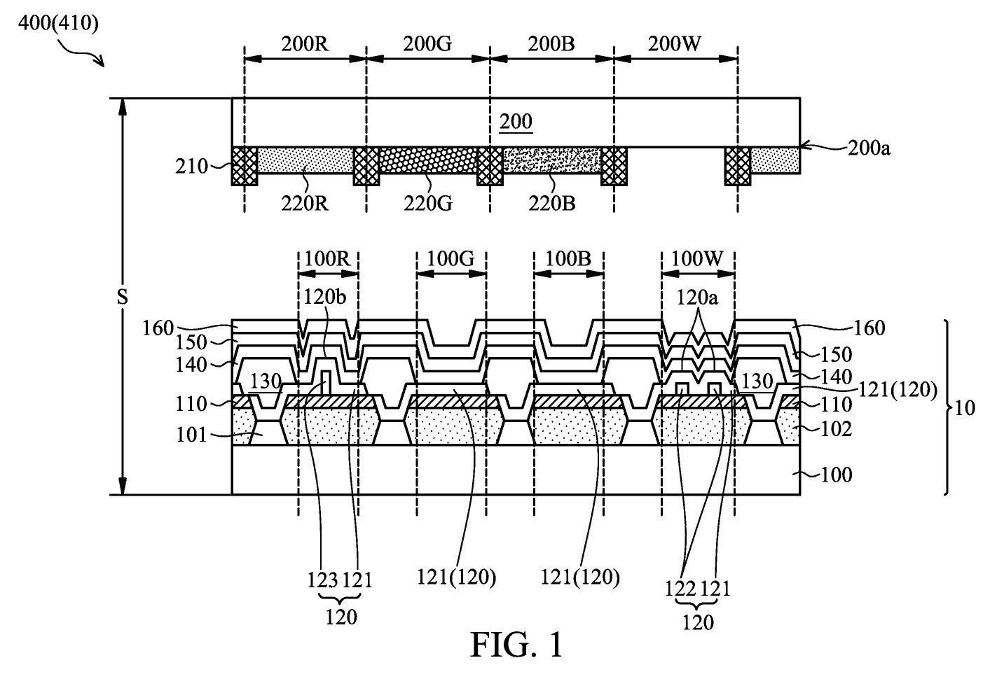

Referring to FIG. 1, an illumination device 10 comprises a device substrate 100 and structures formed thereon. A display panel 400 of a system for displaying images comprises the illumination device 10, and may further comprises an opposite substrate 200 and structures formed thereon.

The illumination device 10 comprises a device substrate 100, an optically reflective layer 110, a first electrode 120, an illumination layer 140, and a second electrode 150. The illumination device 10 can be a top-emitting type illumination device. The optically reflective layer 110 is formed of a reflective material. The first electrode 120 may be formed of a transparent material such as indium tin oxide (ITO). The second electrode 150 can be formed of a transflective material. The device substrate 100 may be transparent or opaque.

The device substrate 100 is predetermined to be divided into a plurality of illumination regions such as four illumination regions 100R, 100G, 100B, and 100W. Every illumination region is equipped with an optional switch 101, which can be a thin film transistor, disposed on the device substrate 100. If the illumination device 10 is not applied to display panels, the switches 101 may not be disposed on the device substrate 100.

In FIG. 1, a planarization layer 102 is optionally formed on the device substrate 100. If the device substrate 100 comprises the switches 101, openings can be formed in the planarization layer 102 to expose terminals of the switches 101.

The optically reflective layers 110 corresponding to partial illumination regions are formed above the device substrate 100. For example, the planarization layer 102 is formed in each of the illumination regions 100R, 100G, 100B, and 100W, and the optically reflective layer 110 is formed overlying the planarization layer 102. The optically reflective layer 110 can be formed of aluminum or other optically reflective materials. Then, a layer of the first electrodes 120 is formed on the device substrate 100, wherein the first electrodes 120 in the illumination regions 100R, 100G, 100B, and 100W are disposed on the optically reflective layer 110. In this embodiment, the first electrodes 120 in the illumination regions 100R and 100W comprise bumps 120b and 120a. In other embodiments, the first electrode 120 in at least one of the illumination regions may comprise a bump or bumps of any types and any quantities, controlling the microcavities in every illumination region and adjusting light spectrums emitted from every illumination region.

In FIG. 1, the aspect profiles of the bumps 120b and 120a are determined by the stacking structure of the first electrodes 120 comprising an electrode base layer 121 and island-like transparent layers 123 and 122. The electrode base layer 121 is disposed in every illumination region, and preferably formed of the same material as that of the island-like transparent layers 122 and 123, decreasing the quantities of heterogeneous interfaces along the optical paths. The first electrode 120 in the illumination region 100R comprises the electrode base layer 121 covering the island-like transparent layers 123. The first electrode 120 in the illumination region 100W comprises the electrode base layer 121 covering the island-like transparent layers 122. The first electrodes 120, disposed in the illumination regions 100G and 100B without any bumps, comprise the electrode base layer 121, but do not have any island-like transparent layers. Further, stacking sequences between the electrode base layer 121 and the island-like transparent layers 122, 123 of the bumps 120a and 120b can be reversed.

In FIG. 1, the bump 120a and the island-like transparent layer 122 are respectively different from the bump 120b and the island-like transparent layer 123 in quantity, cross-sectional shape, and thickness. In other embodiments, the arrangements of the bump(s) and the island-like transparent layer(s) of the first electrode 120 in one of the illumination region is respectively different from that of the first electrode 120 in any other illumination region in quantity, cross-sectional shape, thickness, arranged patterns, aspect profiles, or combinations thereof.

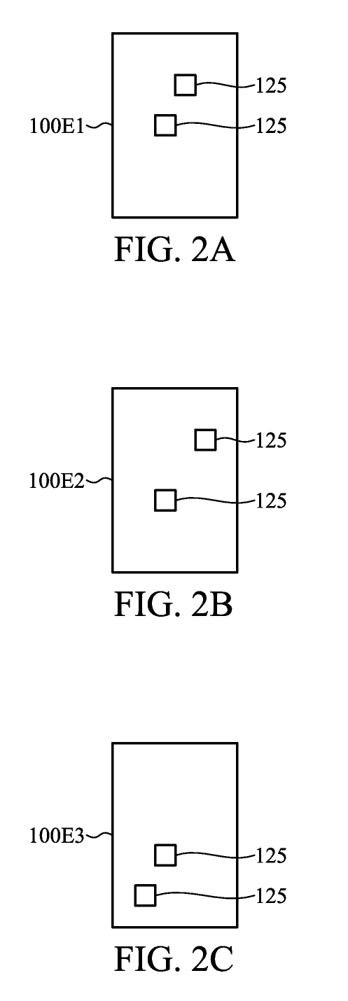

Referring to FIGS. 2A through 2C, the constitution of bumps 125 are similar with or equivalent to those of the bumps 120a and 120b shown in FIG. 1. The interval between the bumps 125 in an illumination region 100E1 in FIG. 2A is different from that between the bumps 125 in an illumination region 100E2 in FIG. 2B, and thus, the bumps 125 in the illumination regions 100E1 and 100E2 are arranged in different patterns. While the bumps 125 in the illumination regions 100E1 and 100E3 in FIGS. 2A and 2C are arranged in the same pattern, the positions of the bumps 125 in the illumination region 100E1 relative to the boundaries of the illumination region 100E1 are different from those of the bumps 125 in the illumination region 100E3 relative to the boundaries of the illumination region 100E3. Thus, the aspect profile of the illumination region 100E1 and the bumps 125 therein is different from that of the illumination region 100E3 and the bumps 125 therein. The types of different arrangements of bumps 125 in the different illumination aforementioned regions can be applied to the bumps in every illumination region shown in FIG. 1.

The island-like transparent layers 122 and 123 can be formed by subsequent processes according to the required thicknesses of the bumps 120a and 120b. An overall transparent electrode layer (not shown) is formed overlying the optically reflective layer 110, followed by formation of a resist layer (not shown) overlying the transparent electrode layer. Then, a typical lithography step can be performed by utilization of a mask comprising a pattern of the island-like transparent layers 122 and 123, followed by etching the transparent electrode layer, thus completing the island-like transparent layers 122 and 123 of a transparent and electrically conductive material. In some embodiments, the island-like transparent layers 122 and 123 with different thicknesses can be formed by utilization of a mask comprising patterns with different optical transparency in the lithography step. Next, the electrode base layer 121 of a transparent and electrically conductive material is coated overlying an overall surface of a structure of the device substrate 100 where the island-like transparent layers 122 and 123 are formed, and covers the island-like transparent layers 122 and 123, revealing the aspect profiles of the bumps 120a and 120b and completing the first electrodes 120, optionally followed by lithography and etching steps, electrically isolating the first electrodes 120 in every illumination region. Thus, the microcavities of the illumination device can be controlled by operation of only one step of a combination of material deposition and patterning. At this time, the first electrodes 120 in every illumination region are electrically isolated from each other. Further, optional pixel definition layers 130 can be formed overlying the first electrode 120 among the illumination regions 100R, 100G, 100B, and 100W as required. The pixel definition layers 130 are formed of a transparent dielectric, assisting electric isolation between the first electrodes 120.

Then, an illumination layer 140 is formed overlying the first electrodes 120. The illumination layer 140 can be an organic electroluminescence illumination layer comprising several stacking layers, which include a hole injection layer (HIL), a hole transport layer (HTL), a main illumination layer, an electron transport layer (ETL), an electron injection layer (EIL), and etc. arranged in a sequence from the interface between the first electrodes 120 and the illumination layer 140, for example. When the pixel definition layers 130 are formed, the illumination layer 140 covers the pixel definition layers 130. Next, a second electrode 150 is formed overlying the illumination layer 140. The optically reflective layer 110, the first electrodes 120, the illumination layer 140, and the second electrode 150 of this embodiment can be formed of any known materials and known fabrication methods, and thus detailed descriptions thereof are abbreviated.

In this embodiment, an organic light emitting diode comprises the optically reflective layer 110, the first electrodes 120, the illumination layer 140, and the second electrode 150. In an embodiment of the present invention, the microcavity between the optically reflective layer 110 and the second electrode 150 are controlled by controlling arrangements of the bumps of the first electrodes 120, providing more adjustable factors for achieving a required frequency of an emitting light more accurately in contrast to prior art. In the prior art, the microcavity only can be controlled by controlling the thickness of the microcavity spacer layer or the transparent electrode. Further, the bumps of the first electrodes 120 can be formed by an additional step of a combination of film deposition and patterning, decreasing the production cycle time and process cost. Moreover, the optical paths of light reflected by the optically reflective layer 110 pass through the bumps of the first electrodes 120. Thus, the variances between lengths of the optical paths of light with different emitting angles from the illumination device viewed can be decreased by appropriate arrangement of the bumps, widening the viewing angle of a system for displaying images of an embodiment of the invention.

In FIG. 1, an optional passivation layer 160 can be formed overlying the second electrode 150 as required. The passivation layer 160 can be formed of a transparent dielectric layer with chemical passivity.

The display panel 400 further comprises an opposite substrate 200. There is a space S between the parallel substrates 200 and 100. Thus, light rays from the illumination regions 100R, 100G, 100B, and 100W of the device substrate 100 reach and respectively pass through the corresponding light transmissive regions 200R, 200G, 200B, and 200W of the opposite substrate 200. A light shielding layer 210 can be disposed overlying an incident surface 200a receiving light from the illumination regions 100R, 100G, 100B, and 100W among the light transmissive regions 200R, 200G, 200B, and 200W. The light shielding layer 210 can be formed of metals, polymers, or other light shielding materials with low optical reflection.

In this embodiment, light rays from the illumination regions 100R, 100G, 100B, and 100W are all white, and thus, it is necessary to dispose a layer of color filters in at least some of the light transmissive regions of the opposite substrate 200. Regarding the sequentially arranged light transmissive regions 200R, 200G, 200B, and 200W, for example, a red light color filter layer 220R, a green light color filter layer 200G and a blue light color filter layer 200B are respectively disposed in the light transmissive regions 200R, 200G, and 200B, but no color filter layer is disposed in the light transmissive region 200W. As a result, a red light pixel region is formed by a combination of the illumination region 100R and the light transmissive region 200R, a green light pixel region is formed by a combination of the illumination region 100G and the light transmissive region 200G, a blue light pixel region is formed by a combination of the illumination region 100B and the light transmissive region 200B, and a white light pixel region is formed by a combination of the illumination region 100W and the light transmissive region 200W.

In other embodiments, the illumination layer 140 in the illumination regions 100R, 100G, 100B, and 100W can respectively emit red, green, blue, and white light rays, and thus, no color filter layer is required.

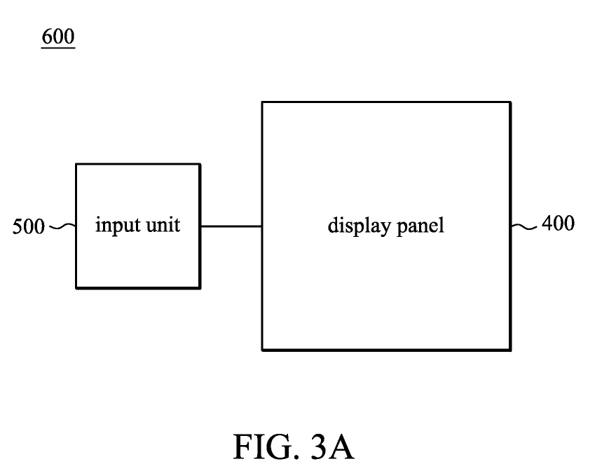

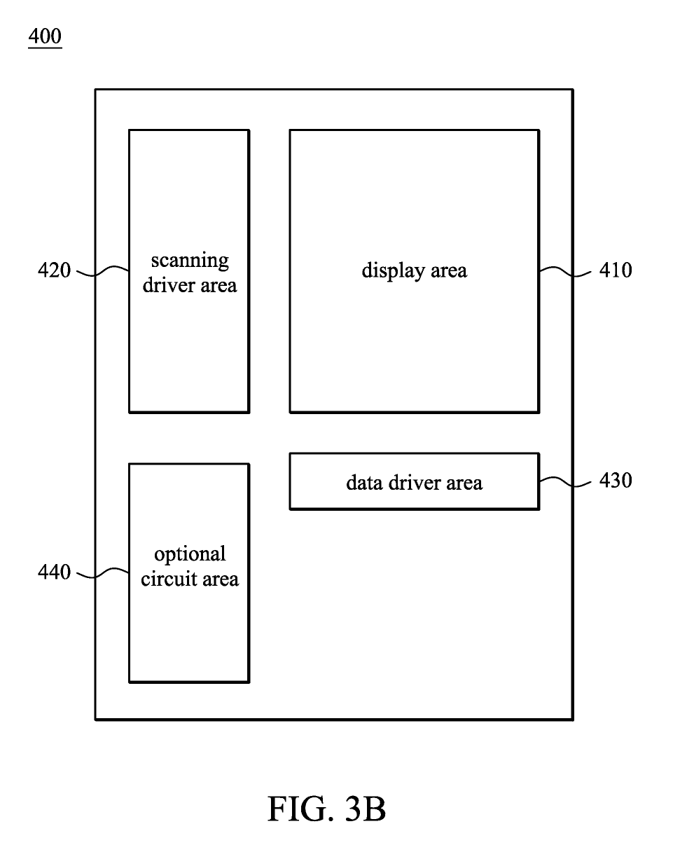

FIGS. 3A and 3B show a system for displaying images of another preferred embodiment of the invention. The system comprises a display panel 400 or an electronic device 600.

As shown in FIG. 3A, the display panel 400 can be utilized for fabricating various electronic devices 600 comprising the display panel 400 and an input unit 500. The input unit 500 is coupled to the display panel 400, inputting signals, such as image signals, into the display panel 400 for displaying images. The electronic device 600 can be a cell phone, a digital camera, a personal digital assistant (PDA), a notebook computer, a desktop computer, a television, a car display, or a portable digital video disc (DVD) player.

FIG. 3B shows an exemplary layout of the display panel 400. The display panel 400 comprises a display area 410, a scanning driver area 420, a data driver area 430, and an optional circuit area 440. The display area 410 comprises a plurality of the switches 101 shown in FIG. 1. The scanning driver area 420 and the data driver area 430 are disposed by sides of the display area 410. The scanning driver area 420 applies electrical voltage to pixel electrodes in the display area 410. The data driver area 430 applies electrical voltage to gate electrodes of the thin film transistors in the display area 410.

Next, the effects of embodiments of the invention are verified by utilization of the display panels of the subsequent Comparative Example, Experimental Example 1, and Experimental Example 2. The process conditions and materials of the display panels of the three examples follow the aforementioned descriptions for the display panel 400 shown in FIG. 1, and all of the specific conditions can be utilized in any embodiments of the invention but cannot limit the claim scope of this application.

First, controlled factors of the display panels of the three examples are subsequently listed.

The material of the device substrates 100 was glass with a thickness between 0.3 mm and 0.7 mm. The switches 101 were polycrystalline silicon type thin film transistors. The planarization layers 102 were organic polymers or inorganic oxides, and between 2 μm and 3 μm thick. The optically reflective layers 110 were aluminum alloys and between 500 Å and 3000 Å thick. The pixel definition layers 130 were organic polymers or inorganic oxides, and between 0.1 μm and 5 μm thick. The illumination layers 140 comprised hole injection layers, hole transport layers, main illumination layers, electron transport layers, and electron injection layers. The second electrodes 150 were indium tin oxide and between 500 Å and 3000 Å thick. The passivation layers 160 were silicon oxide, and between 0.1 μm and 10 μm thick. The opposite substrates 200 were glass and between 0.3 mm and 0.7 mm thick. The light shielding layers 210 were formed. The layers of color filters comprised red light color filter layers 220R, green light color filter layers 200G and blue light color filter layers 200B. The values of the space S were between 1 μm and 10 μm.

Next, variable factors and conditions of the display panels of the three examples are subsequently listed.

(a) The Comparative Example: The first electrode 120 without bumps, that is, consisting of the electrode base layers 121 only, were made of indium tin oxide with thickness of 800 Å. The hole transport layer was formed of NPB (N,N′-diphenyl-N,N′-bis(1-naphthyl)-1,1′-biphenyl-4,4′-diamine) with thickness of 300 Å.

(b) The Experimental Example 1: The first electrode 120 comprised an 800 Å thick electrode base layer 121 and a pair of island-like transparent layers 122, both of which were 300 Å thick. The electrode base layer 121 and the island-like transparent layers 122 were both made of indium tin oxide. The hole transport layer was formed of NPB with thickness of 300 Å.

(c) The Experimental Example 2: The conditions of the first electrode 120 was the same as those in the experiment example 1. The hole transport layer was formed of NPB with thickness of 1700 Å.

Chromaticity coordinates (defined by CIE 1931 standard) of light from the display panels of the Comparative Example, the Experimental Example 1, and the Experimental Example 2 were measured and listed in the subsequent Table 1.

TABLE 1

| | white | | white | | white | | | | | | | |
|---|---|---|---|---|---|---|---|---|---|---|---|---|
| | light in | | light in | | light in | | | | | | | |
| | CIE, and | | CIE, and | | CIE, and | | | | | | | |
| | viewing | | viewing | | viewing | | red | | green | | blue | |
| | angle is 0 | | angle is 45 | | angle is 60 | | light in | | light in | | light in | |
| | degree | | degrees | | degrees | | CIE | | CIE | | CIE | |
| | CIE x | CIE y | CIE x | CIE y | CIE x | CIE y | CIE x | CIE y | CIE x | CIE y | CIE x | CIE y |
| Comparative | 0.25 | 0.30 | 0.35 | 0.23 | 0.41 | 0.29 | 0.66 | 0.33 | 0.14 | 0.55 | 0.12 | 0.11 |
| Example | | | | | | | | | | | | |
| Experimental | 0.32 | 0.27 | 0.35 | 0.29 | 0.36 | 0.30 | 0.66 | 0.33 | 0.27 | 0.57 | 0.13 | 0.14 |
| Example 1 | | | | | | | | | | | | |
| Experimental | 0.33 | 0.31 | 0.31 | 0.31 | 0.30 | 0.32 | 0.66 | 0.33 | 0.27 | 0.57 | 0.13 | 0.14 |
| Example 2 | | | | | | | | | | | | |

According to the results shown in Table 1, the colorimetric purity performances of white light, red light, green light, and blue light provided by the display panels of the Experimental Examples 1 and 2 having the first electrodes 120 comprising bumps, both performed better than those provided by the display panel of the Comparative Example having the first electrodes 120 without bumps. Further, regarding the performance of wider viewing angle, the chrominance differences of the white light provided by the display panels of the Experimental Examples 1 and 2 between viewing angles of 0 degree, 45 degrees, and 60 degrees were all less than 0.02, and the wider viewing angle performances provided by the display panels of the Experimental Examples 1 and 2 were both better than that of the display panel of the Comparative Example.

While the invention has been described by way of example and in terms of preferred embodiment, it is to be understood that the invention is not limited thereto. To the contrary, it is intended to cover various modifications and similar arrangements (as would be apparent to those skilled in the Art). Therefore, the scope of the appended claims should be accorded the broadest interpretation so as to encompass all such modifications and similar arrangements.

What is claimed is:

1. An illumination device, comprising:
a substrate comprising a plurality of illumination regions;
a first electrode provided on the substrate, and having a first bump disposed in a first illumination region of the plurality of the illumination regions;
an illumination layer provided on the first electrode; and
a second electrode provided on the illumination layer.

2. The device as claimed in claim 1, wherein the first electrode comprises an electrode base layer and a first island-like transparent layer, the electrode base layer is disposed in all of the plurality of the illumination regions, and the first island-like transparent layer is disposed in the first illumination region, corresponding to the first bump.

3. The device as claimed in claim 2, wherein the electrode base layer is transparent.

4. The device as claimed in claim 2, wherein the first island-like transparent layer is disposed underlying the electrode base layer.

5. The device as claimed in claim 2, wherein the first island-like transparent layer is disposed overlying the electrode base layer.

6. The device as claimed in claim 2, wherein the first electrode further comprises a second bump disposed in a second illumination region of the plurality of the illumination regions.

7. The device as claimed in claim 6, wherein the first electrode further comprises a second island-like transparent layer in the second illumination region, corresponding to the second bump.

8. The device as claimed in claim 7, wherein the second island-like transparent layer is disposed underlying the electrode base layer.

9. The device as claimed in claim 7, wherein the second island-like transparent layer is disposed overlying the electrode base layer.

10. The device as claimed in claim 7, wherein the arrangement of the first island-like transparent layer is different from that of the second island-like transparent layer in quantity, cross-sectional shape, thickness, arranged patterns, aspect profiles, or combinations thereof.

11. The device as claimed in claim 7, wherein the first and second illumination regions illuminate light of different colors.

12. The device as claimed in claim 2, wherein the second electrode is transflective.

13. The device as claimed in claim 1, further comprising a reflective layer overlying the substrate, underlying the first electrode, and corresponding to the plurality of the illumination regions.

14. A system for displaying images, comprising:
a display panel comprising an illumination device of claim 1; and
an input unit coupled to the display panel and providing an input signal to the display panel for displaying images.

15. A method for fabricating an illumination device, comprising:
providing a substrate comprising a plurality of illumination regions having a first illumination region and a second illumination region;
forming an electrode base layer of a first electrode overlying the substrate in each of the plurality of illumination regions;
forming a first island-like transparent layer of the first electrode overlying the substrate in the first illumination region;
forming an illumination layer overlying the first electrode; and
forming a second electrode overlying the illumination layer.

16. The method as claimed in claim 15, wherein the formation of the electrode base layer is prior to the formation of the first island-like transparent layer.

17. The method as claimed in claim 15, wherein the formation of the electrode base layer is posterior to the formation of the first island-like transparent layer.

18. The method as claimed in claim 15, further comprising forming a second island-like transparent layer in the second illumination region, wherein the arrangement of the first island-like transparent layer is different from that of the second island-like transparent layer.

19. The method as claimed in claim 18, wherein the formation of the electrode base layer is prior to the formation of the second island-like transparent layer.

20. The method as claimed in claim 18, wherein the formation of the electrode base layer is posterior to the formation of the second island-like transparent layer.
